(19) United States
(12) Patent Application Publication
(10) Pub. No.: US 2024/0282660 A1
(43) Pub. Date: Aug. 22, 2024

(54) SEMICONDUCTOR DEVICE

(71) Applicant: FUJI ELECTRIC CO., LTD., Kawasaki-shi (JP)

(72) Inventor: Kenshi TERASHIMA, Matsumoto-city (JP)

(73) Assignee: FUJI ELECTRIC CO., LTD., Kawasaki-shi (JP)

(21) Appl. No.: 18/398,043

(22) Filed: Dec. 27, 2023

(30) Foreign Application Priority Data
Feb. 21, 2023 (JP) 2023-025035

(51) Int. Cl. H01L 23/367; H01L 25/16

(52) U.S. Cl. CPC H01L 23/3675; H01L 25/165; H01L 24/45; H01L 24/48; H01L 24/49; H01L 25/162; H01L 2224/45124; H01L 2224/45139; H01L 2224/45144; H01L 2224/45147; H01L 2224/48137; H01L 2224/48227; H01L 2224/49111; H01L 2224/49112; H01L 2224/49175

(57) ABSTRACT

A semiconductor device, including: a semiconductor chip bonded to a substrate; a heat dissipation base including a fastening portion connected to a heat dissipation portion, the substrate being disposed in a substrate area on the heat dissipation portion, the fastening portion having a fastening hole formed therein; and a case including a protection portion beside an opening area, the protection portion having a fixing hole formed therein corresponding to the fastening hole, the case being disposed on the heat dissipation base so that the substrate is accommodated in the opening area and the protection portion is disposed on the fastening portion. A boundary between the fastening portion and the heat dissipation portion is located outside the opening area of the case in the plan view, and the fastening portion is located lower than the front surface of the heat dissipation portion in a side view of the semiconductor device.

### CROSS-REFERENCE TO RELATED APPLICATION

This application is based upon and claims the benefit of priority of the prior Japanese Patent Application No. 2023-025035, filed on Feb. 21, 2023, the entire contents of which are incorporated herein by reference.

### BACKGROUND OF THE INVENTION

### 1. Field of the Invention

The embodiments discussed herein relate to a semiconductor device.

### 2. Background of the Related Art

There is a semiconductor device that includes a heat dissipation plate with a trapezoid portion and an insulated substrate on which semiconductor elements are mounted and which is directly bonded to the trapezoid portion (see, for example, Japanese Laid-open Patent Publication No. 2003-086741). In addition, there is another semiconductor device that includes an insulated substrate and a metal base plate that has an area where the insulated substrate is disposed and a thin area that is thinner than the area (see, for example, Japanese Laid-open Patent Publication No. 2017-010970).

### SUMMARY OF THE INVENTION

According to one aspect, there is provided a semiconductor device, including: a semiconductor chip; a substrate, with the semiconductor chip bonded to a front surface thereof; a heat dissipation base of a plate shape, the heat dissipation base including: a heat dissipation portion, and a fastening portion connected to the heat dissipation portion without overlapping each other in a plan view of the semiconductor device, the heat dissipation portion having a substrate area set on a front surface thereof, the substrate being disposed in the substrate area, the fastening portion having a fastening hole formed therein; and a case of a frame shape, the case including an opening area at a center thereof and a protection portion beside the opening area, the protection portion having a fixing hole formed therein corresponding to the fastening hole, the case being disposed on the heat dissipation base so that the substrate is accommodated in the opening area and the protection portion is disposed on the fastening portion, wherein a boundary between the fastening portion and the heat dissipation portion is located outside the opening area of the case in the plan view, and the boundary or the fastening portion is located lower than the front surface of the heat dissipation portion in a side view of the semiconductor device.

The object and advantages of the invention will be realized and attained by means of the elements and combinations particularly pointed out in the claims.

It is to be understood that both the foregoing general description and the following detailed description are exemplary and explanatory and are not restrictive of the invention.

### BRIEF DESCRIPTION OF THE DRAWINGS

FIG. 1 is a plan view of a semiconductor device according to a first embodiment;

FIG. 2 is a sectional view of the semiconductor device along a short-side direction according to the first embodiment;

FIG. 3 is a sectional view of the semiconductor device along a long-side direction according to the first embodiment;

FIG. 4 is a flowchart illustrating a semiconductor device manufacturing method according to the first embodiment;

FIG. 5 illustrates a heat dissipation base included in the semiconductor device according to the first embodiment;

FIG. 6 is a plan view of an insulated circuit substrate on which semiconductor chips are disposed and which is included in the semiconductor device according to the first embodiment;

FIG. 7 illustrates a case attachment step (pre-attachment) included in the semiconductor device manufacturing method according to the first embodiment;

FIG. 8 illustrates the case attachment step (post-attachment) included in the semiconductor device manufacturing method according to the first embodiment;

FIG. 9 is a sectional view illustrating how to fasten the semiconductor device to a mounting object according to the first embodiment;

FIG. 10 illustrates a heat dissipation base included in a semiconductor device according to the first embodiment (variation 1-1);

FIG. 11 illustrates a heat dissipation base included in a semiconductor device according to the first embodiment (variation 1-2);

FIGS. 12A and 12B illustrate a heat dissipation base included in a semiconductor device according to the first embodiment (variation 1-3);

FIG. 13 is a plan view of a heat dissipation base included in a semiconductor device according to a second embodiment;

FIGS. 14A and 14B are sectional views of the heat dissipation base included in the semiconductor device according to the second embodiment;

FIG. 15 is a sectional view of the semiconductor device along a long-side direction according to the second embodiment; and

FIG. 16 is a sectional view of the semiconductor device along a short-side direction according to the second embodiment.

### DETAILED DESCRIPTION OF THE INVENTION

Hereinafter, embodiments will be described with reference to the accompanying drawings. In the following description, the terms “front surface” and “top surface” refer to an X-Y plane facing up (in the +Z direction) in a semiconductor device 1 illustrated in drawings. Similarly, the term “up” refers to an upward direction (the +Z direction) in the semiconductor device 1 illustrated in the drawings. The terms “rear surface” and “bottom surface” refer to an X-Y plane facing down (in the −Z direction) in the semiconductor device 1 illustrated in the drawings. Similarly, the term “down” refers to a downward direction (the −Z direction) in the semiconductor device 1 illustrated in the drawings. The same directionality applies to other drawings, as appropriate. The expression “located higher” indicates a higher position (in the +Z direction) in the semiconductor device 1 illustrated in the drawings. Similarly, the expression “located lower” indicates a lower position (in the −Z direction) in the semiconductor device 1 illustrated in the drawings. The terms “front surface,” “top surface,” “up,” “rear surface,” “bottom surface,” “down,” and “side surface” are used for convenience to describe relative positional relationships, and do not limit the technical ideas of the embodiments. For example, the terms “up” and “down” are not always related to the vertical directions to the ground. That is, the “up” and “down” directions are not limited to the gravity direction. In addition, in the following description, the term “main component” refers to a component contained at a volume ratio of 80 vol % or more. The expression “being approximately equal” may allow an error range of ±10%. In addition, the expressions “being perpendicular,” “being orthogonal,” and “being parallel” may allow an error range of ±10%.

### First Embodiment

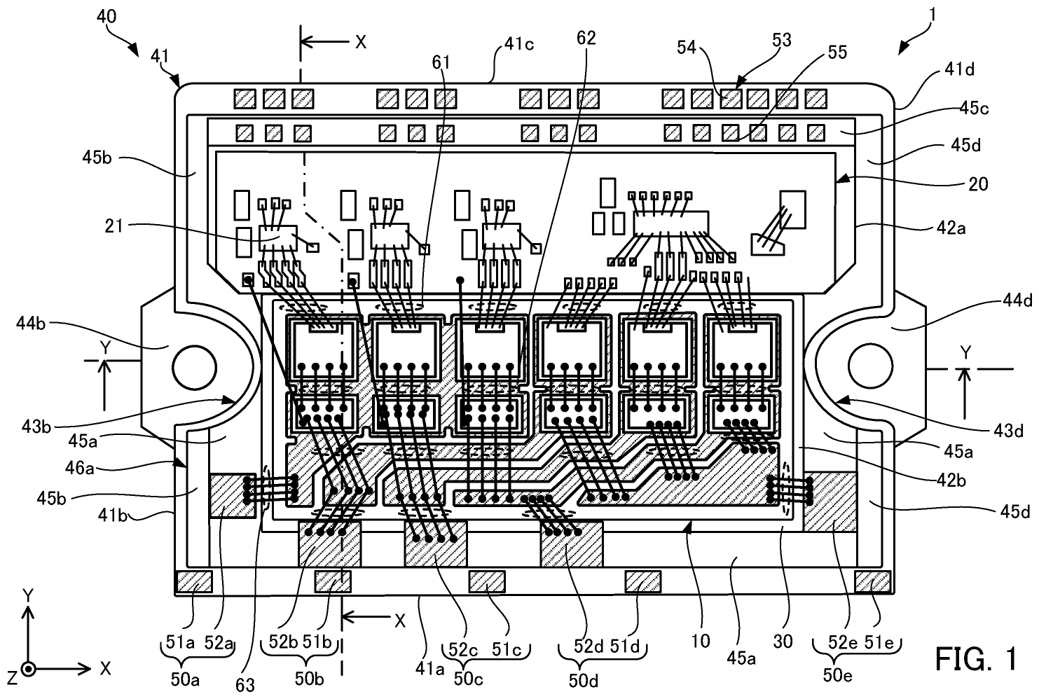

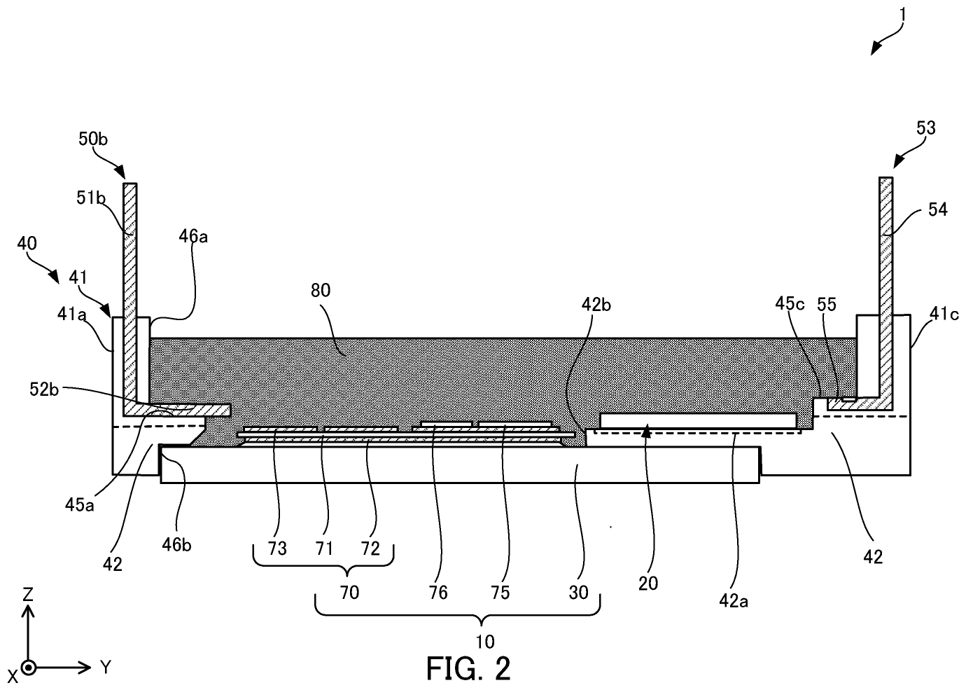

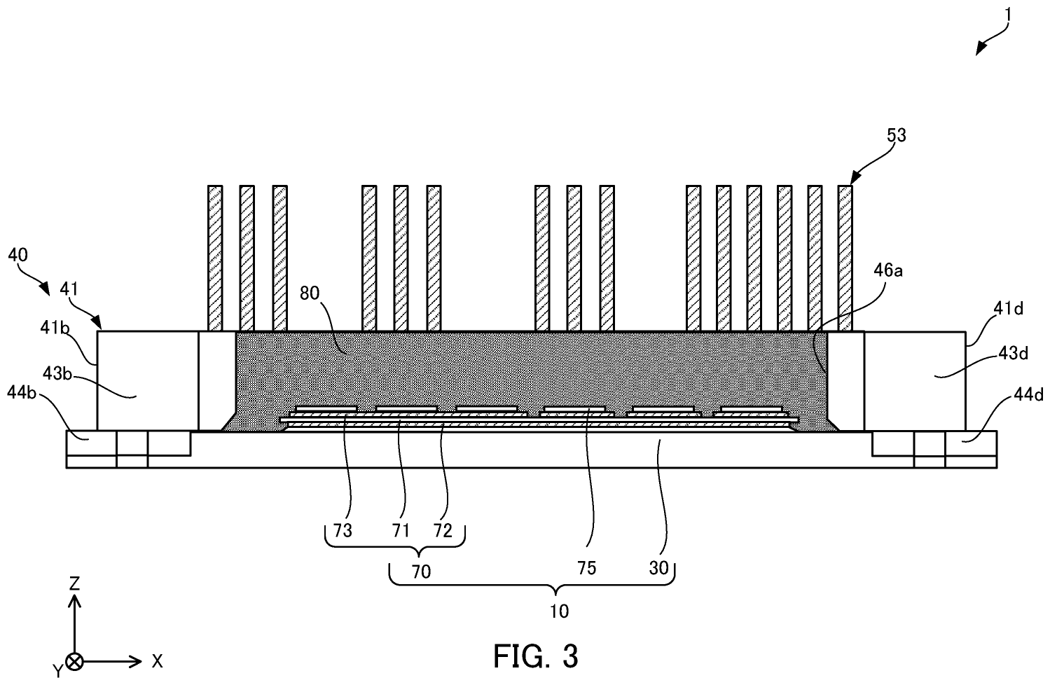

A semiconductor device 1 according to a first embodiment will be described with reference to FIGS. 1 to 3. FIG. 1 is a plan view of the semiconductor device according to the first embodiment. FIG. 2 is a sectional view of the semiconductor device along a short-side direction according to the first embodiment. FIG. 3 is a sectional view of the semiconductor device along a long-side direction according to the first embodiment. In this connection, the illustration of a sealing member 80 is omitted in FIG. 1. FIG. 2 is a sectional view taken along a dash-dotted line X-X of FIG. 1. FIG. 3 is a sectional view taken along a dash-dotted line Y-Y of FIG. 1. The illustration of control wires 61, electrical wires 62, main current wires 63, and control integrated circuits (ICs) 21 is omitted in FIGS. 2 and 3.

The semiconductor device 1 includes a semiconductor unit 10, a printed circuit board 20, and a case 40 accommodating the semiconductor unit 10 and printed circuit board 20. The semiconductor unit 10 includes an insulated circuit substrate 70, first semiconductor chips 75 and second semiconductor chips 76 mounted on the insulated circuit substrate 70, and a heat dissipation base 30. In this connection, the semiconductor unit 10 includes six sets each containing a first semiconductor chip 75 and a second semiconductor chip 76.

The insulated circuit substrate 70 includes an insulating plate 71, a metal plate 72, and circuit patterns 73. The insulating plate 71 is made of ceramics with high thermal conductivity as a main component. For example, the ceramics contain aluminum oxide, aluminum nitride, or silicon nitride as a main component. In addition, the insulating plate 71 is rectangular in a plan view.

The metal plate 72 is made of a metal with high thermal conductivity as a main component. The corners of the metal plate 72 may be rounded. Examples of the metal include aluminum, iron, silver, copper, and an alloy containing at least one of these. The metal plate 72 is rectangular in a plan view, and is formed on the entire rear surface of the insulating plate 71 except the outer edge thereof. Plating may be performed on the surface of the metal plate 72 to improve its corrosion resistance. Examples of the plating material used here include nickel, a nickel-phosphorus alloy, and a nickel-boron alloy.

The circuit patterns 73 form a predetermined circuit. For example, three sets each containing a first semiconductor chip 75 and a second semiconductor chip 76 are mounted on a circuit pattern 73. The illustrated circuit patterns 73 have a total of six sets each containing a first semiconductor chip 75 and a second semiconductor chip 76 disposed thereon. The number of sets each containing a first semiconductor chip 75 and a second semiconductor chip 76 is not limited to six, and an appropriate number of sets for the specifications of the semiconductor device 1 may be disposed on the circuit patterns 73. The plurality of circuit patterns 73 are formed on the front surface of the insulating plate 71. In addition, the circuit patterns 73 are made of a metal with high electrical conductivity as a main component. Examples of the metal here include silver, copper, nickel, and an alloy containing at least one of these. Plating may be performed on the surfaces of the circuit patterns 73 to improve their corrosion resistance. Examples of the plating material used here include nickel, a nickel-phosphorus alloy, and a nickel-boron alloy. These circuit patterns 73 are formed by forming a conductive plate or foil on one surface of the insulating plate 71 and etching the conductive plate or foil. Alternatively, the circuit patterns 73 are formed by pasting conductive plates to one surface of the insulating plate 71. The circuit patterns 73 will be described in detail later.

As the insulated circuit substrate 70, a direct copper bonding (DCB) substrate or an active metal brazed (AMB) substrate may be used. In the semiconductor unit 10 configured as above, the shapes, positions, and quantity of the circuit patterns 73 and the positions and quantity of the first semiconductor chips 75 and second semiconductor chips 76 are illustrated just as an example in FIGS. 1 to 3, and are desirably determined according to design and others.

The first semiconductor chips 75 and second semiconductor chips 76 are power semiconductor chips made of silicon as a main component. The first semiconductor chips 75 each include a switching element. For example, the switching element may be an integrated gate bipolar transistor (IGBT) or a power metal-oxide-semiconductor field-effect transistor (MOSFET). In the case of an IGBT, each first semiconductor chip 75 has a collector electrode serving as an input electrode on the rear surface thereof and has a gate electrode serving as a control electrode and an emitter electrode serving as an output electrode on the front surface thereof. In the case of a power MOSFET, each first semiconductor chip 75 has a drain electrode serving as an input electrode on the rear surface thereof and has a gate electrode serving as a control electrode and a source electrode serving as an output electrode on the front surface thereof.

The rear surfaces of the first semiconductor chips 75 are bonded to the circuit patterns 73 via a bonding material (not illustrated). In the present embodiment, the bonding material may be a solder or a sintered metal. The solder may be a lead-free solder containing a predetermined alloy as a main component. For example, the predetermined alloy is any one of a tin-silver alloy, a tin-zinc alloy, and a tin-antimony alloy. The solder may contain an additive such as copper, bismuth, indium, nickel, germanium, cobalt, or silicon. As the sintered metal, aluminum or copper is used, for example.

The second semiconductor chips 76 each include a diode element. For example, the diode element may be a free-wheeling diode (FWD) such as a Schottky barrier diode (SBD) or a P-intrinsic-N (PiN) diode. Each second semiconductor chip 76 of this type has a cathode electrode serving as an output electrode on the rear surface thereof and has an anode electrode serving as an input electrode on the front surface thereof. The rear surfaces of the second semiconductor chips 76 are bonded to the circuit patterns 73 via the bonding material.

Instead of the first semiconductor chips 75 and second semiconductor chips 76, semiconductor chips each including a reverse-conducting (RC)-IGBT may be used. The RC-IGBT has both an IGBT function and an FWD function. Alternatively, instead of the first semiconductor chips 75 and second semiconductor chips 76, semiconductor chips each including a power MOSFET made of silicon carbide may be used. Each semiconductor chip of this type has an FWD together with a power MOSFET.

The heat dissipation base 30 is made of a metal with high thermal conductivity as a main component. Examples of the metal include copper, aluminum, and an alloy containing at least one of these. Plating may be performed on the surface of the heat dissipation base 30 to improve its corrosion resistance. Examples of the plating material used here include nickel, a nickel-phosphorus alloy, and a nickel-boron alloy. The insulated circuit substrate 70 is disposed on the heat dissipation base 30 via the above-mentioned bonding material. In this connection, the heat dissipation base 30 will be described in detail later.

The printed circuit board 20 is provided in a print area 42a of the case 40. The printed circuit board 20 provided in the print area 42a is located adjacent to the insulated circuit substrate 70 in plan view. This printed circuit board 20 includes an insulating plate and a plurality of upper circuit patterns formed on the front surface of the insulating plate. In addition, the printed circuit board 20 may include a plurality of lower circuit patterns on the rear surface of the insulating plate.

The insulating plate has a flat plate shape and is made of an insulating material. As the insulating material, a material obtained by immersing a base body into a resin is used. For example, this base body is primarily formed of paper, glass fabric, or glass nonwoven fabric. Examples of the resin include a phenolic resin, an epoxy resin, and a polyimide resin. Specific examples of the insulating plate include a paper phenolic substrate, a paper epoxy substrate, a glass epoxy substrate, a glass polyimide substrate, and a glass composite substrate. The insulating plate is rectangular in plan view as well. The corners of the insulating plate may be rounded or chamfered.

The plurality of upper circuit patterns and the plurality of lower circuit patterns have a predetermined pattern shape so as to form a predetermined circuit. The upper circuit patterns and lower circuit patterns are made of a material with high electrical conductivity. Examples of the material here include silver, copper, nickel, and an alloy containing at least one of these. Plating may be performed on the surfaces of the upper circuit patterns and lower circuit patterns to improve their corrosion resistance. Examples of the plating material used here include nickel, a nickel-phosphorus alloy, and a nickel-boron alloy.

For example, this printed circuit board 20 may be formed in the following manner. A metal foil is attached to each of the front surface and rear surface of the insulating plate, and a resist is printed in a predetermined shape. Then, the metal foils on the front and rear surfaces of the insulating plate are etched with the printed resists as masks, and the remaining resists are removed. By doing so, the upper and lower circuit patterns are formed on the front and rear surfaces of the insulating plate, respectively.

In addition, the printed circuit board 20 includes, as electronic components, control ICs 21 electrically connected to the upper circuit patterns. In the present embodiment, the control ICs 21 are electrically and mechanically connected to control electrodes such as the gate electrodes of the first semiconductor chips 75 with control wires 61, as illustrated in FIG. 1. The control ICs 21 apply control voltage to the first semiconductor chips 75 at predetermined timing. In this connection, the control wires 61 used here are made of a material with high electrical conductivity. Examples of the material here include gold, silver, copper, aluminum, and an alloy containing at least one of these. In addition, the diameters of the control wires 61 are in the range of 100 μm to 250 μm, inclusive, for example. In this connection, other requisite electronic components than the control ICs 21 may be mounted on the printed circuit board 20. Examples of such electronic components include a thermistor, a capacitor, a resistor, a current sensor, and a temperature sensor.

In addition, for example, in the insulated circuit substrate 70, electrical wires 62 are provided to make electrical and mechanical connections between each first semiconductor chip 75 and the corresponding second semiconductor chip 76 and between each second semiconductor chip 76 and one of the circuit patterns 73. Furthermore, main current wires 63 are provided to make electrical and mechanical connections between each main current connection terminal 50a to 50e (internal connection portions 52a to 52e), which will be described later, and one of the circuit patterns 73 of the insulated circuit substrate 70. The electrical wires 62 and main current wires 63 are made of the above-described material with high electrical conductivity as well. In addition, the diameters of the electrical wires 62 and main current wires 63 are in the range of 100 μm to 1.00 mm, inclusive, for example.

The case 40 will now be described. The case 40 includes a bottom portion 42, a frame portion 41 integrally formed with the bottom portion 42 so as to surround the outer periphery of the bottom portion 42, and protection portions 44b and 44d formed on the rear surfaces of side walls 41b and 41d, which will be described later, of the frame portion 41. In this connection, as exemplified in FIG. 2, the bottom portion 42 is formed on the rear surface of the frame portion 41. In FIG. 2, the boundary between the bottom portion 42 and the rear surface of the frame portion 41 (side walls 41a and 41c in FIG. 2) is indicated by a broken line. In addition, the case 40 includes the main current connection terminals 50a to 50e and control terminals 53. In this connection, in the following description, the main current connection terminals 50a to 50e may be referred to as main current connection terminals 50 without distinction among them.

The case 40 is formed by injection molding using a thermoplastic resin, for example. Note that the case 40 is formed including the main current connection terminals 50 and the control terminals 53. Examples of the thermoplastic resin include a polyphenylene sulfide resin, a polybutylene terephthalate resin, a polybutylene succinate resin, a polyamide resin, and an acrylonitrile butadiene styrene resin.

The bottom portion 42 is rectangular in plan view. In the front surface of the bottom portion 42, an opening area 42b, which is an insulated circuit substrate area, and a print area 42a are set. In this connection, as exemplified in FIG. 2, the print area 42a is set on the front surface of the bottom portion 42 as indicated by a broken line. The insulated circuit substrate 70 is disposed in the opening area 42b, and the printed circuit board 20 is disposed in the print area 42a. That is, the print area 42a and opening area 42b are set in the front surface of the bottom portion 42 in plan view, as illustrated in the upper part and lower part of FIG. 1, respectively. The opening edge of the opening area 42b may be tapered toward the rear surface side of the opening area 42b. In addition, a bottom opening 46b is formed in the rear surface of the bottom portion 42. The bottom opening 46b includes an opening at a position corresponding to the opening area 42b. The semiconductor unit 10 is attached from the rear surface side of the bottom opening 46b provided in the bottom portion 42. More specifically, the heat dissipation base 30 is attached to the bottom portion 42 in the bottom opening 46b such that the insulated circuit substrate 70 is exposed in the opening area 42b. In this connection, the heat dissipation base 30 is attached to the bottom portion 42 in the bottom opening 46b using an adhesive material (not illustrated). The rear surface of thus attached heat dissipation base 30 may project outward (downward in FIGS. 2 and 3) beyond the rear surface of the bottom portion 42. Alternatively, the rear surface of the heat dissipation base 30 may be flush with the rear surface of the bottom portion 42.

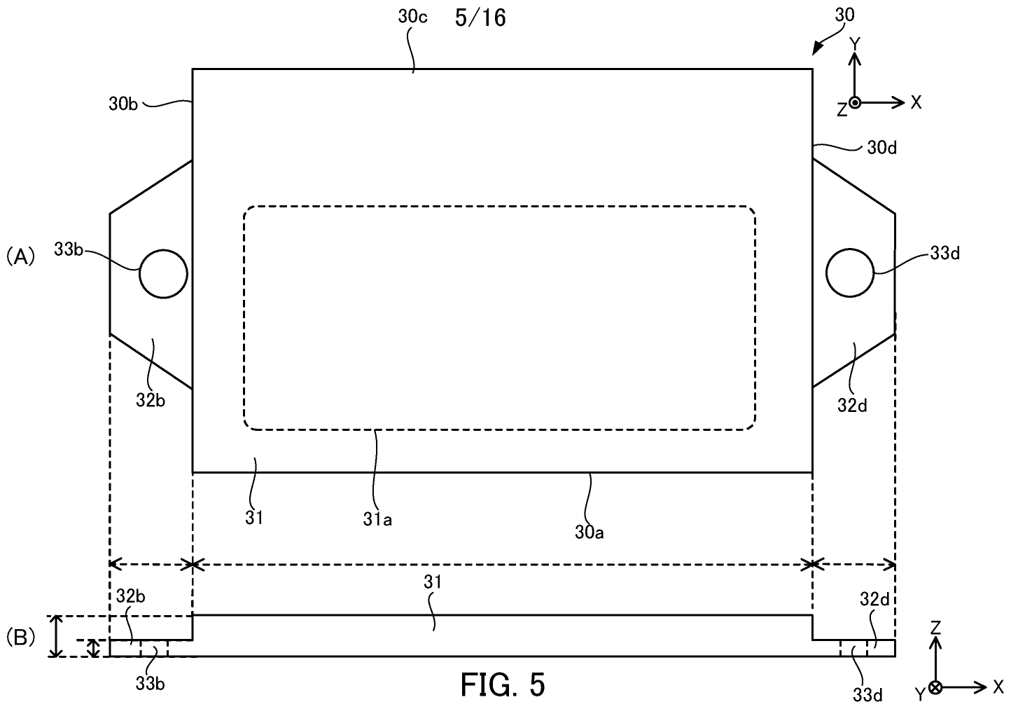

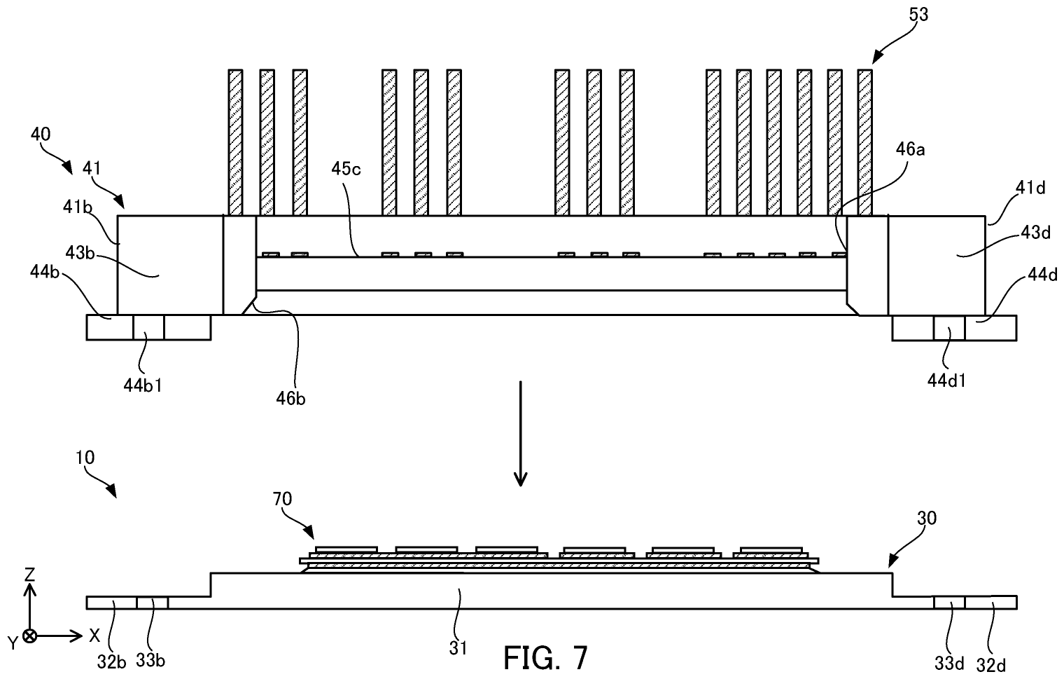

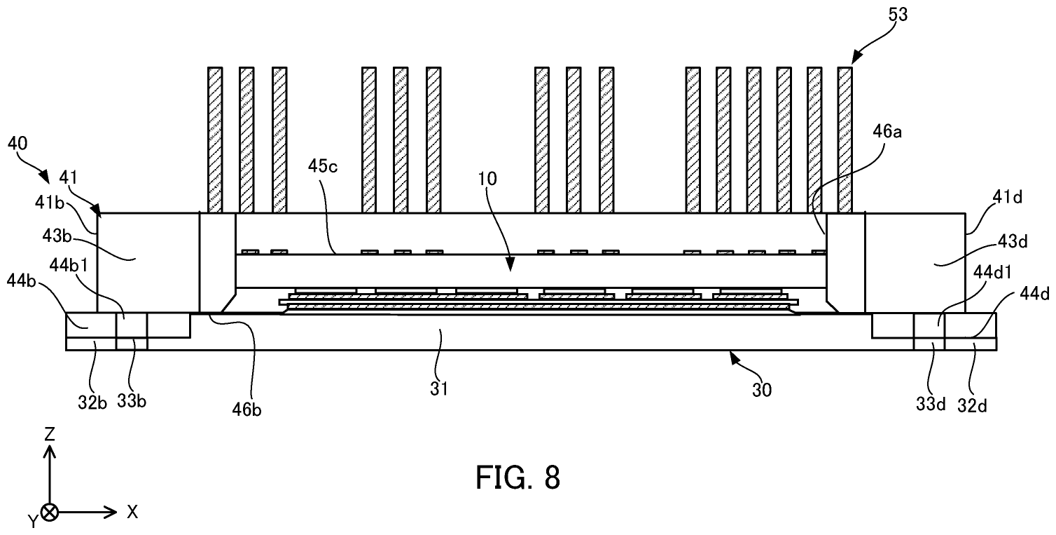

The protection portions 44b and 44d cover fastening portions 32b and 32d of the heat dissipation base 30 illustrated in FIG. 5, respectively. In addition, in the protection portions 44b and 44d, fixing holes 44b1 and 44d1 are formed at positions corresponding to fastening holes 33b and 33d formed in the heat dissipation base 30, as illustrated in FIGS. 7 and 8. In addition, the fixing holes 44b1 and 44d1 are partially surrounded by insertion portions 43b and 43d of the case 40, respectively, in plan view. In this connection, a metal ring (whose description is omitted) may be provided at each fixing hole 44b1 and 44d1 of the protection portions 44b and 44d. In addition, the thickness of the protection portions 44b and 44d corresponds to the height of the steps between each fastening portion 32b and 32d and the heat dissipation portion 31, which will be described later, of the heat dissipation base 30. In plan view, the protection portions 44b and 44d may have an isosceles trapezoid shape, as with the fastening portions 32b and 32d, which will be described later, of the heat dissipation base 30.

The rear surfaces of the protection portions 44b and 44d are located lower (in the −Z direction) than the rear surfaces of the side walls 41a and 41c. That is, in the case 40, the total thickness (in the ±Z directions) of the side wall 41b and protection portion 44b and the total thickness (in the ±Z directions) of the side wall 41d and protection portion 44d are greater than the thicknesses (in the ±Z directions) of the side walls 41a and 41c.

The adhesive material for bonding the heat dissipation base 30 to the bottom portion 42 in the bottom opening 46b may be a thermosetting resin-based adhesive or an elastomer-based adhesive, for example. The thermosetting resin-based adhesive contains an epoxy resin or a phenolic resin as a main component, for example. The elastomer-based adhesive contains a silicone rubber or a chloroprene rubber as a main component, for example. The adhesive material preferably contains an epoxy resin or a silicone rubber as a main component.

The print area 42a is set adjacent to the opening area 42b on the side of the opening area 42b opposite to the side wall 41a on the front surface of the bottom portion 42. The printed circuit board 20 is disposed in the print area 42a via the adhesive material, for example.

The frame portion 41 has a frame shape in plan view. This frame portion 41 has the side walls 41a to 41d integrally formed respectively at the sides of the bottom portion 42. In addition, all the side walls 41a to 41d have the same height. The side walls 41a and 41c are respectively provided at the long sides of the bottom portion 42. Stepped portions 45a and 45c are formed on the inner sides of the side walls 41a and 41c, respectively. In this connection, the stepped portion 45a extends to the inner sides of the side walls 41b and 41d, which will be described later, that correspond to the short sides of the semiconductor unit 10. The side walls 41b and 41d are respectively provided at the short sides of the bottom portion 42. Stepped portions 45b and 45d are formed on the inner sides of the side walls 41b and 41d, respectively. The main current connection terminals 50a to 50e are integrally formed with the side wall 41a and bottom portion 42 so to be aligned along the side wall 41a. In addition, the control terminals 53 are integrally formed with the side wall 41c and bottom portion 42 so as to be aligned along the side wall 41c.

The main current connection terminals 50 each have an L shape in side view, as illustrated in FIG. 2. More specifically, each main current connection terminal 50 is formed by bending a plate-shaped member into an L shape. In this connection, FIG. 2 illustrates the main current connection terminal 50b as an example. The main current connection terminal 50b includes an external connection portion 51b and an internal connection portion 52b. The external connection portion 51b has one end extending upward from the top surface of the side wall 41a and the other end integrally connected to one end of the internal connection portion 52b inside the side wall 41a. The other end of the internal connection portion 52b is exposed on the stepped portion 45a. The other end of the internal connection portion 52b is electrically and mechanically connected to a circuit pattern 73 via the main current wires 63. Likewise, the main current connection terminals 50a and 50c to 50e include external connection portions 51a and 51c to 51e and internal connection portions 52a and 52c to 52e, respectively. The external connection portions 51a and 51c to 51e each have one end extending upward from the top surface of the side wall 41a and the other end integrally connected to one end of the corresponding one of the internal connection portions 52a and 52c to 52e inside one of the side walls 41a, 41b, and 41d. The other ends of the internal connection portions 52a and 52c to 52e are exposed on the stepped portion 45a. The other ends of the internal connection portions 52a and 52c to 52e are electrically and mechanically connected to the corresponding circuit patterns 73 with the main current wires 63. The main current connection terminals 50 are made of a material with high electrically conductivity. Examples of the material here include copper, aluminum, nickel, and an alloy containing at least one of these. Plating may be performed on the surfaces of the main current connection terminals 50 to improve their corrosion resistance. Examples of the plating material used here include nickel and a nickel alloy.

The control terminals 53 each have an L shape in side view, as illustrated in FIG. 2. More specifically, each control terminal 53 is formed by bending a prismatic or cylindrical member in an L shape. Each control terminal 53 has an external connection portion 54 extending upward from the side wall 41c and an internal connection portion 55 exposed on the stepped portion 45c of the side wall 41c. The internal connection portion 55 and the printed circuit board 20 may be electrically connected to each other with wires that are not illustrated.

In this manner, the printed circuit board 20 is electrically connected to the internal connection portions 55 of the control terminals 53. When receiving a control signal from the printed circuit board 20, the control ICs 21 output the control signal to the gate electrodes of the first semiconductor chips 75 via the control wires 61. The control terminals 53 are made of a material with high electrical conductivity. Examples of the material here include copper, aluminum, nickel, and an alloy containing at least one of these. Plating may be performed on the surfaces of the control terminals 53 to improve their corrosion resistance. Examples of the plating material used here include nickel and a nickel alloy.

The insertion portions 43b and 43d may be provided in the side walls 41b and 41d, respectively. When the semiconductor device 1 is screwed to a mounting object with screws, as will be described later, the screws are inserted in the insertion portions 43b and 43d.

A cooling unit (not illustrated) may be attached to the rear surface (the rear surface of the heat dissipation base 30) of the semiconductor device 1 via a solder, a silver solder, a thermal grease, or a heat dissipation sheet, for example, to improve the heat dissipation property. For example, the cooling unit here is made of a metal with high thermal conductivity as a main component. Examples of the metal here include aluminum, iron, silver, copper, and an alloy containing at least one of these. In addition, a heatsink or a cooling device using cold water may be used as the cooling unit. In addition, such a cooling unit may be integrally mounted to the rear surface of the heat dissipation base 30.

The sealing member 80 is applied from a top opening 46a of the case 40 accommodating the above-described components until the sealing member 80 fills the top opening 46a. The sealing member 80 contains a thermosetting resin and an inorganic filler contained in the thermosetting resin. For example, the thermosetting resin contains, as a main component, at least one selected from the group including an epoxy resin, a phenolic resin, and a melamine resin. The thermosetting resin preferably contains an epoxy resin as a main component. In addition, as the inorganic filler, an inorganic containing silicon oxide as a main component is used. In addition, it is possible to maintain high flame resistance without blending flame retardant such as halogen-based, antimony-based, or metal hydroxide-based retardant. The inorganic filler accounts for 70 vol % or more and up to 90 vol % of the sealing material.

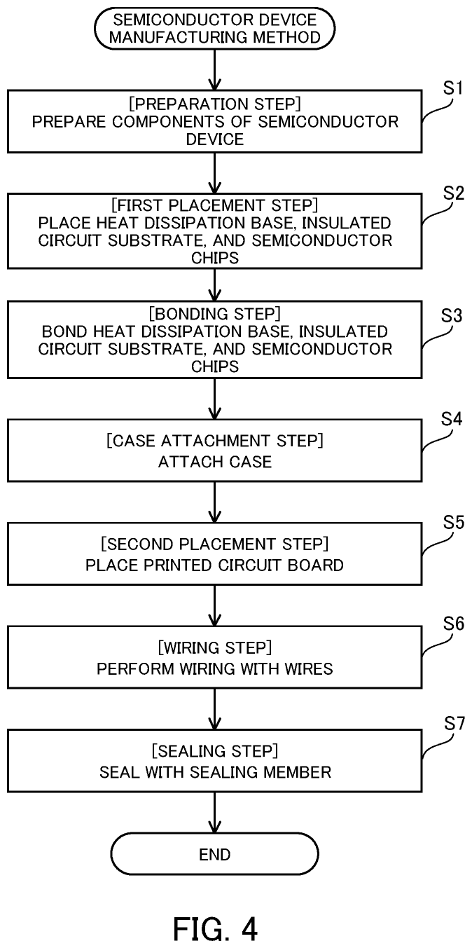

The following describes a method of manufacturing the semiconductor device 1 with reference to FIG. 4. FIG. 4 is a flowchart illustrating a semiconductor device manufacturing method according to the first embodiment. First, the components of the semiconductor device 1 are prepared (step S1). For example, the components include the first semiconductor chips 75, the second semiconductor chips 76, the insulated circuit substrate 70, the heat dissipation base 30, the case 40, and the sealing material of the sealing member 80. Other components needed for manufacturing the semiconductor device 1 are also prepared. In addition, any device needed for manufacturing the semiconductor device 1 may be prepared.

As an example of the components, the heat dissipation base 30 will be described with reference to FIG. 5. FIG. 5 illustrates a heat dissipation base included in the semiconductor device according to the first embodiment. In this connection, (A) of FIG. 5 is a plan view of the heat dissipation base 30, and (B) of FIG. 5 is a side view of (A) of FIG. 5 seen in the +Y direction.

As described earlier, the heat dissipation base 30 is made of a metal with high thermal conductivity as a main component. The metal used here contains a copper-based material as a main component. In addition, nickel plating may be performed. The heat dissipation base 30 includes a heat dissipation portion 31 and fastening portions 32b and 32d. The heat dissipation portion 31 is rectangular in plan view. The heat dissipation portion 31 is surrounded on its four sides by side surfaces 30a to 30d in order. The side surfaces 30a and 30c correspond to the long sides, whereas the side surfaces 30b and 30d correspond to the short sides. In addition, a unit area 31a where the insulated circuit substrate 70 is disposed is set, as indicated by a broken line, on the front surface of the heat dissipation portion 31. In this connection, the thickness of the heat dissipation portion 31 may be in the range of 2 mm to 6 mm, inclusive, for example, and may be 3 mm in this embodiment.

The fastening portions 32b and 32d are connected to the heat dissipation portion 31 without overlapping each other in plan view. The fastening portions 32b and 32d are integrally provided on the side surfaces 30b and 30d of the heat dissipation portion 31, respectively. That is, the fastening portions 32b and 32d project outward from the side surfaces 30b and 30d of the heat dissipation portion 31, respectively, in the long-side direction. The boundaries between each fastening portion 32b and 32d and the heat dissipation portion 31 cross the portions (the fastening portions 32b and 32d) projecting from the side surfaces 30b and 30d of the heat dissipation portion 31 in plan view. These fastening portions 32b and 32d each have a trapezoid shape (an isosceles trapezoid shape) in plan view. The base sides of the fastening portions 32b and 32d are integrally provided on the side surfaces 30b and 30d of the heat dissipation portion 31, respectively. In this connection, in plan view, the base side of the fastening portion 32b means the +X-side side surface thereof, and the base side of the fastening portion 32d means the −X-side side surface thereof. In this connection, in plan view, the top side of the fastening portion 32b means the −X-side side surface thereof, and the top side of the fastening portion 32d means the +X-side side surface thereof. Alternatively, the fastening portions 32b and 32d may be rectangular. In this case, the top-side side surface of each fastening portion 32b and 32d may have the same length as the bottom-side side surface thereof. In addition, the top sides and base sides of the fastening portions 32b and 32d may have the same length as the side surfaces 30b and 30d of the heat dissipation portion 31. In addition, the fastening holes 33b and 33d are respectively formed at positions corresponding to the fixing holes 44b1 and 44d1 of the case 40 in the fastening portions 32b and 32d. The thicknesses of the fastening portions 32b and 32d including their boundaries with the heat dissipation portion 31 are 15% or greater and up to 30% the thickness of the heat dissipation portion 31. In this case, the thicknesses of the fastening portions 32b and 32d may be in the range of 0.5 mm to 1 mm, inclusive, for example. That is, the front surfaces of the fastening portions 32b and 32d are located lower than the front surface of the heat dissipation portion 31. More specifically, the front surface of the fastening portion 32b and the front surface of the heat dissipation portion 31 form a step therebetween, and the height of the step corresponds to the difference in height between the front surface of the fastening portion 32b and the front surface of the heat dissipation portion 31. Likewise, the front surface of the fastening portion 32d and the front surface of the heat dissipation portion 31 form a step therebetween, and the height of the step corresponds to the difference in height between the front surface of the fastening portion 32d and the front surface of the heat dissipation portion 31.

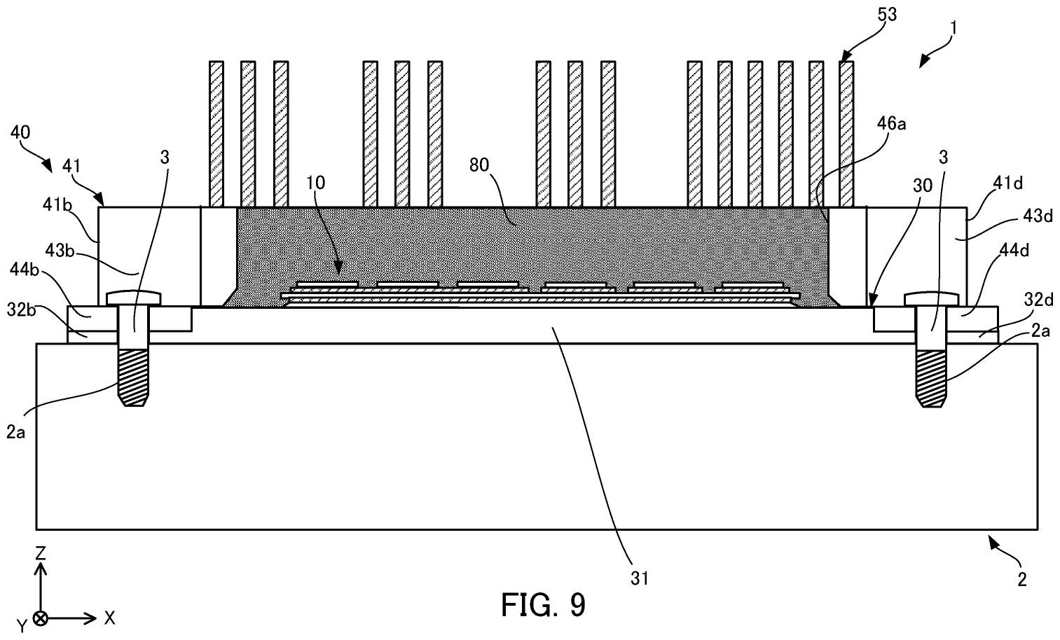

As described earlier, the protection portions 44b and 44d of the case 40 are attached to the fastening portions 32b and 32d, respectively. When the case 40 is attached to the heat dissipation base 30, the boundaries between each fastening portion 32b and 32d and the heat dissipation portion 31 are spaced at least a predetermined distance from the unit area 31a of the heat dissipation base 30 and are located outside the top opening 46a and bottom opening 46b of the case 40 in plan view. As will be described later, when the semiconductor device 1 is fastened to the mounting object 2 (see FIG. 9), the sufficient spaces between each boundary and the unit area 31a ensure a reduction in the impact of stress that is imposed on the insulated circuit substrate 70 due to the fastening of the semiconductor device 1.

This heat dissipation base 30 is manufactured in the following manner. For example, a shape as illustrated in (A) of FIG. 5 in plan view is cut out of a metal plate with uniform thickness. The front surfaces of the portions projecting on the sides are made thinner by grinding, and the fastening holes 33b and 33d are formed. By doing so, the heat dissipation base 30 including the heat dissipation portion 31 and the fastening portions 32b and 32d is obtained. Therefore, at the boundaries between the fastening portions 32b and 32d and the side surfaces 30b and 30d of the heat dissipation portion 31, the fastening portions 32b and 32d are continuously connected to the side surfaces 30b and 30d of the heat dissipation portion 31, respectively. In this connection, the diameters of the fastening holes 33b and 33d may desirably be determined. For example, the area of each fastening portion 32b and 32d is desirably set at least three times the area of each fastening hole 33b and 33d. This setting maintains the strength of the fastening portions 32b and 32d at a certain level or more even when the fastening holes 33b and 33d are formed.

The step surfaces (Z-Y plane) of the side surfaces 30b and 30d of the heat dissipation portion 31 that rise from the fastening portions 32b and 32d may be substantially perpendicular to the front surfaces (X-Y plane) of the fastening portions 32b and 32d. For example, in FIG. 5, the step surfaces may be inclined at an angle in the range of ±5° with respect to a surface (Z-Y plane) perpendicular to the front surfaces (X-Y plane) of the fastening portions 32b and 32d.

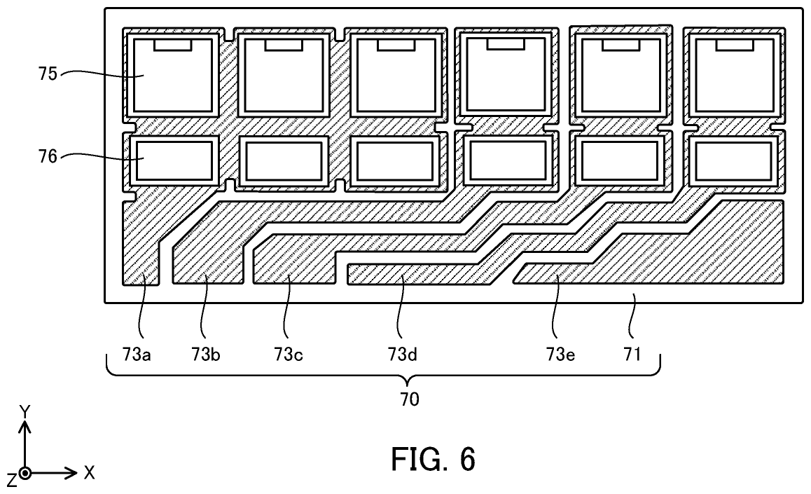

As another example of the components, the insulated circuit substrate 70 will be described with reference to FIG. 6. FIG. 6 is a plan view of an insulated circuit substrate on which semiconductor chips are disposed and which is included in the semiconductor device according to the first embodiment.

As described earlier, the insulated circuit substrate 70 includes the insulating plate 71, metal plate 72, and circuit patterns 73. In this connection, the illustration of the metal plate 72 formed on the rear surface of the insulating plate 71 is omitted in FIG. 6. In addition, FIG. 6 illustrates the case where the first semiconductor chips 75 and second semiconductor chips 76 are disposed on the circuit patterns 73.

The circuit patterns 73 include circuit patterns 73a and 73e. The circuit pattern 73a faces the −X-side short side of the insulating plate 71 and half of the +Y-side long side of the insulating plate 71, and also faces the −X-side end portion of the −Y-side long side of the insulating plate 71. On the circuit pattern 73a, three sets each containing a first semiconductor chip 75 and a second semiconductor chip 76 arranged in the ±Y directions are aligned in the ±X directions. The circuit pattern 73b is formed adjacent to the circuit pattern 73a in the +X direction on the insulating plate 71. One set of a first semiconductor chip 75 and a second semiconductor chip 76 is disposed on the circuit pattern 73b. The circuit patterns 73c and 73d are respectively formed adjacent to the circuit patterns 73b and 73c in the +X direction on the insulating plate 71. In addition, one set of a first semiconductor chip 75 and a second semiconductor chip 76 is disposed on each of the circuit patterns 73c and 73d. The circuit pattern 73e faces the +X-side short side of the insulating plate 71 and the +X-side portion of the −Y-side long side of the insulating plate 71.

Then, a first placement step of placing the insulated circuit substrate 70 on the heat dissipation base 30 and placing the first semiconductor chips 75 and second semiconductor chips 76 is executed (step S2). The insulated circuit substrate 70 is placed in the unit area 31a of the heat dissipation base 30 via the bonding material. In addition, the first semiconductor chips 75 and second semiconductor chips 76 are placed on the circuit patterns 73a to 73d of the insulated circuit substrate 70 via the bonding material in the same manner. In this connection, the bonding material is a solder plate, for example.

Then, a bonding step of bonding the heat dissipation base 30, insulated circuit substrate 70, first semiconductor chips 75, and second semiconductor chips 76, which are arranged in step S2, is executed (step S3). The heat dissipation base 30, insulated circuit substrate 70, first semiconductor chips 75, and second semiconductor chips 76, which are arranged in step S2, are heated to melt the bonding material, and the bonding material is then cured. By doing so, the insulated circuit substrate 70 is bonded to the unit area 31a of the heat dissipation base 30, and the first semiconductor chips 75 and second semiconductor chips 76 are bonded to the circuit patterns 73. In the manner described above, the semiconductor unit 10 is manufactured. In this connection, the heat dissipation base 30 and insulated circuit substrate 70 may warp downward due to the heating in the bonding step.

Then, a case attachment step of attaching the case 40 to the semiconductor unit 10 manufactured in step S3 is executed (step S4). The attachment step will be described with reference to FIGS. 7 and 8. FIG. 7 illustrates a case attachment step (pre-attachment) included in the semiconductor device manufacturing method according to the first embodiment. FIG. 8 illustrates the case attachment step (post-attachment) included in the semiconductor device manufacturing method according to the first embodiment. In this connection, FIGS. 7 and 8 correspond to the sectional view of FIG. 3.

First, as illustrated in FIG. 7, the case 40 is positioned on the heat dissipation base 30 of the semiconductor unit 10. At this time, the bottom opening 46b of the case 40 corresponds to the insulated circuit substrate 70. In addition, the protection portions 44b and 44d of the case 40 correspond to the fastening portions 32b and 32d of the heat dissipation base 30, respectively. Before this positioning, the adhesive material is applied to at least one of the rear surface of the bottom portion 42 of the case 40 and the outer edge of the front surface of the heat dissipation base 30.

After that, the case 40 is moved and attached to the heat dissipation base 30, as illustrated in FIG. 8. The protection portions 44b and 44d of the case 40 are placed on the fastening portions 32b and 32d of the heat dissipation base 30, respectively, so that the fixing holes 44b1 and 44d1 of the case 40 are aligned with the fastening holes 33b and 33d of the heat dissipation base 30, respectively. In addition, the inner walls of the protection portions 44b and 44d of the case 40 facing the top opening 46a come into contact with the steps formed by the fastening portions 32b and 32d and the heat dissipation portion 31, respectively. Furthermore, the insulated circuit substrate 70 having the first semiconductor chips 75 and second semiconductor chips 76 mounted thereon on the heat dissipation base 30 is accommodated in the case 40 from the bottom opening 46b of the case 40.

Then, a second placement step of placing the printed circuit board 20 in the print area 42a of the case 40 is executed (step S5). The printed circuit board 20 is placed in the print area 42a of the case 40 via the adhesive material. In this connection, step S5 is not executed at this timing, but for example, the printed circuit board 20 may be placed in the print area 42a of the case 40 in advance in the preparation step S1.

Then, a wiring step of connecting the components with wires inside the case 40 is executed (step S6). The control ICs 21 of the printed circuit board 20 and the control electrodes of the first semiconductor chips 75 are connected with the control wires 61. The first semiconductor chips 75 and the second semiconductor chips 76 are connected with the electrical wires 62, and the second semiconductor chips 76 and the circuit patterns 73 are connected with the electrical wires 62. The main current connection terminals 50 of the case 40 and the circuit patterns 73 of the insulated circuit substrate 70 are connected with the main current wires 63.

Then, a sealing step of sealing the inside of the case 40 by applying the sealing member 80 from the top opening 46a of the case 40 is executed (step S7). The material of the sealing member 80 is applied from the top opening 46a of the case 40. Once the material is cured into the sealing member 80, the insulated circuit substrate 70 on the heat dissipation base 30, first semiconductor chips 75, second semiconductor chips 76, printed circuit board 20, control wires 61, electrical wires 62, and main current wires 63 are sealed with the sealing member 80. Through the above steps, the semiconductor device 1 of FIGS. 1 to 3 is obtained.

The following describes how to attach the semiconductor device 1 to a mounting object with reference to FIG. 9. FIG. 9 is a sectional view illustrating how to fasten the semiconductor device to a mounting object according to the first embodiment. In this connection, FIG. 9 corresponds to the sectional views of FIGS. 3, 7, and 8.

The semiconductor device 1 is placed on the mounting object 2. The mounting object 2 may be anything that needs the semiconductor device 1 to be placed thereon. For example, the mounting object 2 is a cooling device. Screw holes 2a are formed in the mounting object 2 to allow screws 3 to be screwed therein.

In a situation where the semiconductor device 1 is placed in a substantially flat mounting area of the mounting object 2, the fixing holes 44b1 and 44d1 and fastening holes 33b and 33d of the semiconductor device 1 are respectively aligned with the screw holes 2a of the mounting object 2. Then, the screws 3 are inserted in the fixing holes 44b1 and 44d1 and fastening holes 33b and 33d and are then screwed into the screw holes 2a.

In the semiconductor device 1, the fastening portions 32b and 32d of the heat dissipation base 30 are thinner than the heat dissipation portion 31. Therefore, even if stress is imposed on the heat dissipation base 30 due to the screwing of the screws 3, the fastening portions 32b and 32d deform to thereby reduce the stress. This reduces the chance of warping in the heat dissipation portion 31 of the heat dissipation base 30 and accordingly in the insulated circuit substrate 70 provided on the heat dissipation portion 31, which in turn reduces the occurrence of cracks in the insulated circuit substrate 70 (especially, in the insulating plate 71).

The following describes the case where the heat dissipation base 30 in the semiconductor device 1 has a substantially uniform thickness as a whole, i.e., the case where the fastening portions 32b and 32d and the heat dissipation portion 31 of the heat dissipation base 30 have the same thickness. In this connection, a semiconductor device that will be described now is obtained by modifying the semiconductor device 1 such that the fastening portions 32b and 32d and the heat dissipation portion 31 of the heat dissipation base 30 have the same thickness. In addition, the rear surface of the frame portion 41 of the case 40 is on the same plane. Except for this difference, the semiconductor device has the same configuration as the semiconductor device 1.

As with the semiconductor device 1, the semiconductor device as well is placed on the mounting object 2 and is then fastened thereto by screwing a screw 3 into the fixing hole 44b1 and fastening hole 33b and then screwing a screw 3 into the fixing hole 44d1 and fastening hole 33d. For example, when the semiconductor device is fastened to the mounting object 2 by first screwing the screw 3 into the fixing hole 44b1 and fastening hole 33b, the side of the semiconductor device where the fixing hole 44d1 and fastening hole 33d are located may rise with the fixing hole 44b1 and fastening hole 33b as a fulcrum. Especially, when heating is carried out to bond the insulated circuit substrate 70 to the heat dissipation base 30, the heat dissipation base 30 may warp downward. Then, the insulated circuit substrate 70 is bonded to the warped heat dissipation base 30. In the case where the semiconductor device including the warped heat dissipation base 30 is fastened by screwing the screw 3 into the fixing hole 44b1 and fastening hole 33b, the side of the semiconductor device where the fixing hole 44d1 and fastening hole 33d are located rises significantly.

Then, when the semiconductor device is fastened to the mounting object 2 by screwing the screw 3 into the fixing hole 44d1 and fastening hole 33d, the semiconductor device warps upward as a whole. This causes stress inside the semiconductor device. For example, such warping of the semiconductor device causes stress in the insulated circuit substrate 70 bonded to the heat dissipation base 30 via the bonding member, and a crack may occur, especially in the insulating plate 71 of the insulated circuit substrate 70. In addition, a crack may occur in the bonding material bonding the insulated circuit substrate 70 to the heat dissipation base 30. Such damage occurring inside the semiconductor device reduces the reliability of the semiconductor device.

To deal with this, the semiconductor device 1 includes the first semiconductor chips 75, second semiconductor chips 76, insulated circuit substrate 70, heat dissipation base 30, and case 40. The first semiconductor chips 75 and second semiconductor chips 76 are bonded to the front surface of the insulated circuit substrate 70. The heat dissipation base 30 has a plate shape and includes the heat dissipation portion 31 and the fastening portions 32b and 32d provided at the outer edge of the heat dissipation portion 31 in plan view, the heat dissipation portion 31 having the unit area 31a, where the insulated circuit substrate 70 is disposed, set on the front surface thereof, the fastening portions 32b and 32d having the fastening holes 33b and 33d formed therein. The case 40 has a frame shape, includes the top opening 46a formed at the center thereof and the protection portions 44b and 44d formed at the outer edge thereof and having the fixing holes 44b1 and 44d1 so as to correspond to the fastening holes 33b and 33d, and is arranged on the heat dissipation base 30 so that the insulated circuit substrate 70 is accommodated in the top opening 46a and the protection portions 44b and 44d are placed on the fastening portions 32b and 32d. In the heat dissipation base 30, the boundaries between each fastening portion 32b and 32d and the heat dissipation portion 31 is located outside the top opening 46a of the case 40 in plan view, and the boundaries or the fastening portions 32b and 32d are located lower than the front surface of the heat dissipation portion 31 in side view. This semiconductor device 1 is placed in a substantially flat mounting area of the mounting object 2, and is fastened to the mounting object 2 by screwing the screws 3 into the fixing holes 44b1 and 44d1 and fastening holes 33b and 33d of the semiconductor device 1 and then into the screw holes 2a of the mounting object 2. Since the fastening portions 32b and 32d of the heat dissipation base 30 are thinner than the heat dissipation portion 31, the fastening portions 32b and 32d deform due to stress. This reduces the occurrence of stress inside the semiconductor device 1, and accordingly reduces the occurrence of cracks in the insulated circuit substrate 70 and the bonding member bonding the insulated circuit substrate 70 to the heat dissipation base 30. In addition, since the case 40 is provided with the protection portions 44b and 44d, the frame portion 41 becomes thick around the areas where the fastening is done. This increases the strength of the case 40 and enhances resistance to external impacts and stress caused by the screwing, which results in preventing a reduction in the reliability of the semiconductor device 1.

That is to say, in the heat dissipation base 30 of the semiconductor device 1, the rigidity of the fastening portions 32b and 32d including their boundaries with the heat dissipation portion 31 needs to be less than that of the heat dissipation portion 31. In this case, when the semiconductor device 1 is fastened to the mounting object 2 using the screws 3, the fastening portions 32b and 32d of the heat dissipation base 30 are deformable. In the first embodiment, to achieve this effect of the fastening portions 32b and 32d, the fastening portions 32b and 32d including their boundaries with the heat dissipation portion 31 are made thinner than the heat dissipation portion 31. Some variations of the fastening portions 32b and 32d will now be described.

### (Variation 1-1)

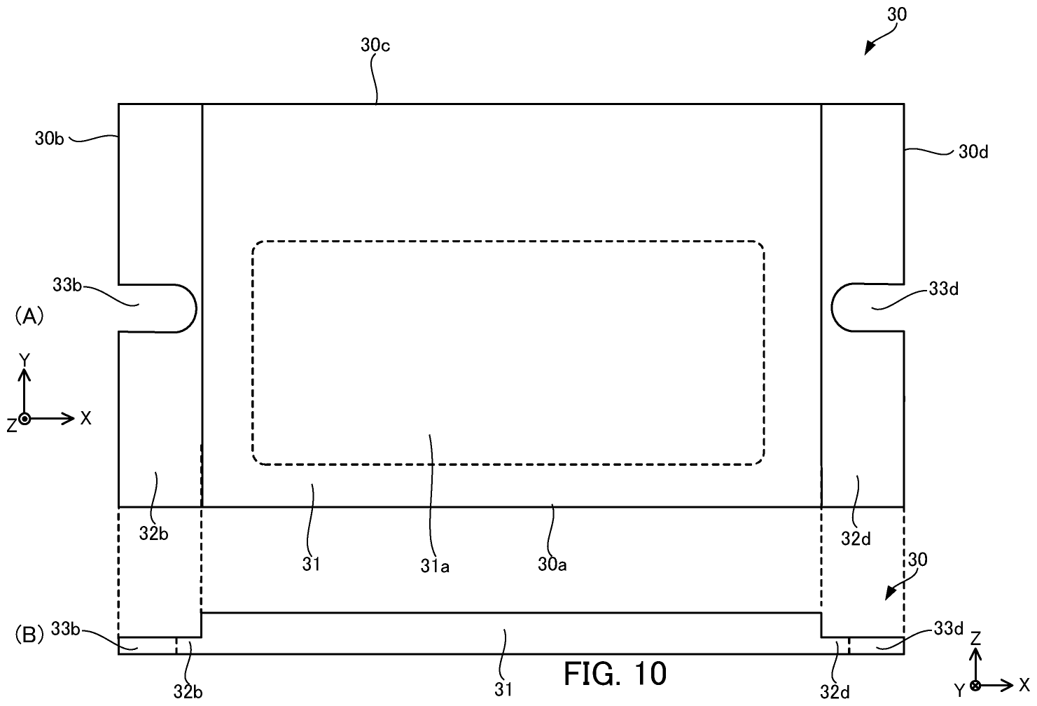

Variation 1-1 will be described with reference to FIG. 10. FIG. 10 illustrates a heat dissipation base included in a semiconductor device according to the first embodiment (variation 1-1). (A) of FIG. 10 is a plan view of a heat dissipation base 30, whereas (B) of FIG. 10 is a side view of the heat dissipation base 30 seen in the +Y direction.

The heat dissipation base 30 of variation 1-1 is rectangular in plan view and is surrounded on its four sides by side surfaces 30a to 30d in order. The side surfaces 30a and 30c correspond to the long sides, whereas the side surfaces 30b and 30d correspond to the short sides. The heat dissipation base 30 includes a heat dissipation portion 31 and fastening portions 32b and 32d. The heat dissipation portion 31 is rectangular in plan view. In this case as well, the heat dissipation portion 31 has a unit area 31a, where the insulated circuit substrate 70 is mounted, set on the front surface thereof, as indicated by a broken line.

The fastening portions 32b and 32d are integrally provided on both sides in the ±X directions of the heat dissipation portion 31. The fastening portions 32b and 32d and heat dissipation portion 31 have the same length in the ±Y directions. That is to say, the boundaries between each fastening portion 32b and 32d and the heat dissipation portion 31 are located a predetermined distance inward from a pair of side surfaces 30b and 30d of the heat dissipation base 30 in the long-side direction, and extend in parallel to the pair of side surfaces 30b and 30d.

In addition, the fastening holes 33b and 33d are formed in the fastening portions 32b and 32d such as to be open in the side surfaces 30b and 30d. In this variation 1-1 as well, the fastening portions 32b and 32d are thinner than the heat dissipation portion 31. That is, the front surfaces of the fastening portions 32b and 32d are located lower than the front surface of the heat dissipation portion 31.

In addition, although this is not illustrated, the case 40 as well has protection portions 44b and 44d that correspond in shape and position to the fastening portions 32b and 32d of the heat dissipation base 30. In the case as well where this case 40 is attached to the heat dissipation base 30 of variation 1-1, the boundaries between each fastening portion 32b and 32d and the heat dissipation portion 31 are located outside the top opening 46a and bottom opening 46b of the case 40 in plan view.

The semiconductor device including the heat dissipation base 30 of variation 1-1 is able to provide the same effects as the semiconductor device 1 of the first embodiment. In this connection, the shapes in plan view of the fastening portions 32b and 32d are illustrated just as an example. As in the first embodiment, the fastening portions 32b and 32d of variation 1-1 may have an isosceles trapezoid shape. In addition, the shapes in plan view of the fastening holes 33b and 33d are illustrated just as an example, and may be circular as in the first embodiment.

### (Variation 1-2)

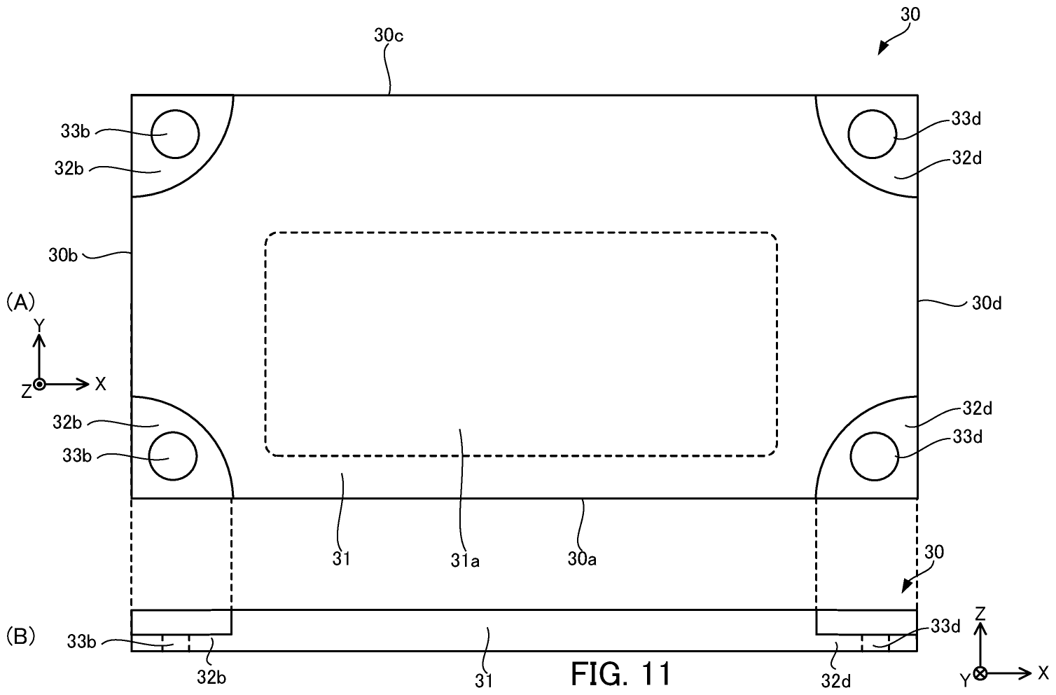

Variation 1-2 will be described with reference to FIG. 11. FIG. 11 illustrates a heat dissipation base included in a semiconductor device according to the first embodiment (variation 1-2). In this connection, (A) of FIG. 11 is a plan view of a heat dissipation base 30, whereas (B) of FIG. 11 is a side view of the heat dissipation base 30 seen in the +Y direction.

The heat dissipation base 30 of variation 1-2 is rectangular in plan view and is surrounded on its four sides by side surfaces 30a to 30d in order. The side surfaces 30a and 30c correspond to the long sides, whereas the side surfaces 30b and 30d correspond to the short sides. The heat dissipation base 30 has fastening holes 33b and 33d at the four corners thereof. This heat dissipation base 30 includes a heat dissipation portion 31 and fastening portions 32b and 32d having the fastening holes 33b and 33d formed therein. The heat dissipation portion 31 has a unit area 31a, where the insulated circuit substrate 70 is mounted, set on the front surface thereof, as indicated by a broken line. The fastening portions 32b and 32d include the fastening holes 33b and 33d, and each have, in plan view, a fan shape with an arc connecting between the side surfaces 30a and 30b, with an arc connecting between the side surfaces 30b and 30c, with an arc connecting between the side surfaces 30c and 30d, or with an arc connecting between the side surfaces 30d and 30a. In addition, these fastening portions 32b and 32d are thinner than the heat dissipation portion 31. In this variation 1-2 as well, the front surfaces of the fastening portions 32b and 32d are located lower than the front surface of the heat dissipation portion 31. In this connection, the shapes in plan view of the fastening portions 32b and 32d are not limited to the fan shape, and may be a rectangular shape. In the case where the fastening portions 32b and 32d have a rectangular shape, however, stress caused by the screwing of screws 3 may concentrate on the corners of the rectangles. To ensure a reduction in the stress, the fastening portions 32b and 32d may preferably have a fan shape without corners.

In addition, although this is not illustrated, the case 40 as well has protection portions that correspond in shape and position to the fastening portions 32b and 32d formed at the four corners of the heat dissipation base 30. In the case as well where this case 40 is attached to the heat dissipation base 30 of variation 1-2, the boundaries between each fastening portion 32b and 32d and the heat dissipation portion 31 are located outside the top opening 46a and bottom opening 46b of the case 40 in plan view. The semiconductor device including this heat dissipation base 30 is able to provide the same effects as the semiconductor device 1 of the first embodiment.

### (Variation 1-3)

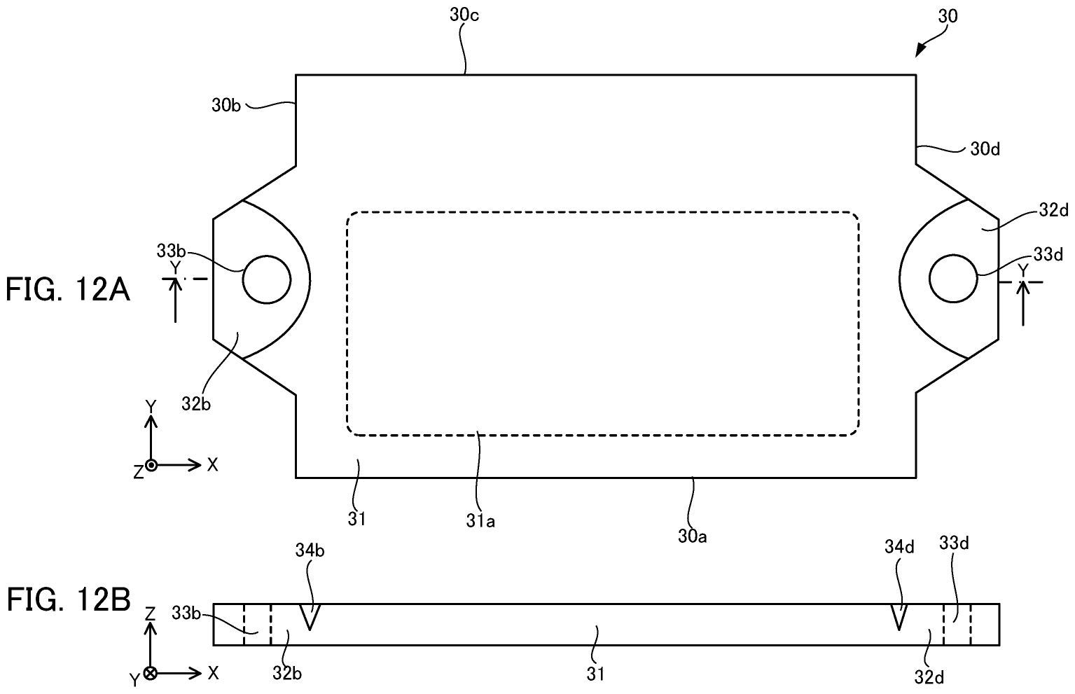

Variation 1-3 will now be described with reference to FIGS. 12A and 12B. FIGS. 12A and 12B illustrate a heat dissipation base included in a semiconductor device according to the first embodiment (variation 1-3). In this connection, FIG. 12A is a plan view of a heat dissipation base 30, whereas FIG. 12B is a sectional view taken along a dash-dotted line Y-Y of FIG. 12A.

The heat dissipation base 30 of variation 1-3 has the same configuration as the heat dissipation base 30 of the first embodiment in plan view. That is, the heat dissipation base 30 includes a heat dissipation portion 31 and portions in an isosceles trapezoid shape projecting from side surfaces 30b and 30d of the heat dissipation portion 31. In this connection, the heat dissipation base 30 of variation 1-3 has a substantially uniform thickness as a whole. The projecting portions include fastening holes 33b and 33d, respectively.

In addition, the heat dissipation base 30 of variation 1-3 has grooves 34b and 34d that are located inward from the fastening holes 33b and 33d (in the ±X directions) and that cross the projecting portions. The areas outside the grooves 34b and 34d are fastening portions 32b and 32d. That is, the grooves 34b and 34d form the boundaries between each fastening portion 32b and 32d and the heat dissipation portion 31. The depths of the grooves 34b and 34d may be set 30% or greater and up to 50% the thickness of the heat dissipation base 30, for example. In addition, the grooves 34b and 34d may have a concave shape, a U-shape, or a V-shape in cross section, for example.

As in the first embodiment, the insulated circuit substrate 70 having the first semiconductor chips 75 and second semiconductor chips 76 disposed thereon is bonded to the heat dissipation base 30 of variation 1-3, and then the case 40 is attached. In this case, the grooves 34b and 34d that are the boundaries between each fastening portion 32b and 32d and the heat dissipation portion 31 are located outside the top opening 46a and bottom opening 46b of the case 40 in plan view. In this connection, the bottom surface of the frame portion 41 of the case 40 may be on the same plane.

As illustrated in FIG. 9, the screws 3 are inserted into the fixing holes 44b1 and 44d1 and fastening holes 33b and 33d of the semiconductor device 1 placed on the mounting object 2, and are then screwed into the screw holes 2a. If stress is caused in the heat dissipation base 30 by the screwing of the screws 3, the fastening portions 32b and 32d deform into the grooves 34b and 34d, thereby reducing the stress. This reduces the change of warping in the heat dissipation portion 31 of the heat dissipation base 30 and accordingly in the insulated circuit substrate 70 provided on the heat dissipation portion 31, which in turn reduces the occurrence of cracks in the insulated circuit substrate 70 (especially, in the insulating plate 71).

In this connection, the grooves 34b and 34d may be formed in parallel to the side surfaces 30b and 30d. For example, in the case where the heat dissipation portion 31 and fastening portions 32b and 32d of the heat dissipation base 30 illustrated in FIG. 5 have the same thickness, the grooves 34b and 34d may be formed on the boundaries between the heat dissipation portion 31 and each fastening portion 32b and 32d. In addition, in the case as well where the heat dissipation portion 31 and fastening portions 32b and 32d of the heat dissipation base 30 illustrated in either FIG. 10 or 11 have the same thickness, the grooves 34b and 34d may be formed on the boundaries. Note, however, that the grooves 34b and 34d need to be formed outside the unit area 31a. In addition, the grooves 34b and 34d are preferably curved in plan view. The grooves 34b and 34d that are curved prevent the stress from concentrating on one location and ensure a reduction in the stress.

### Second Embodiment

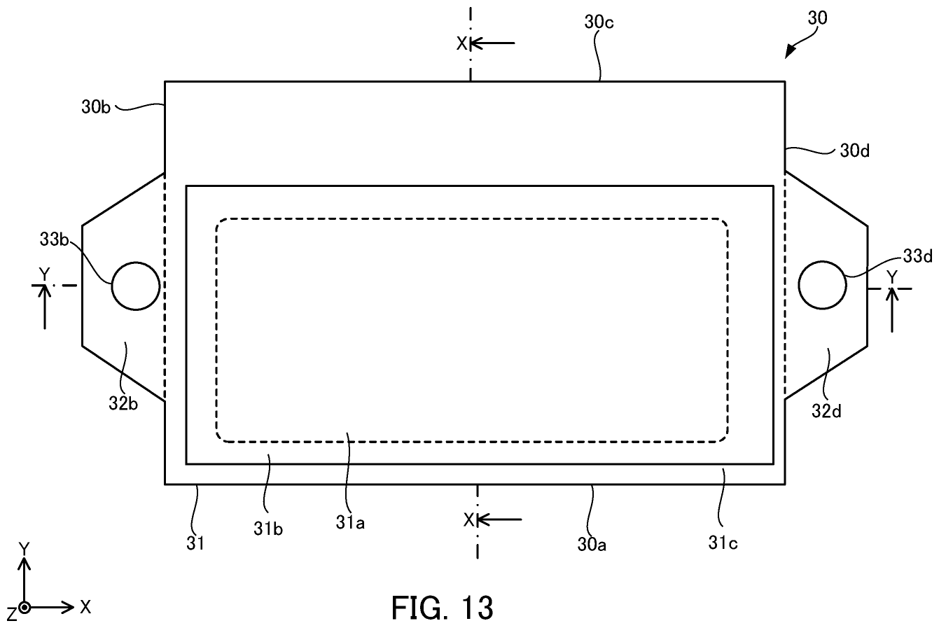

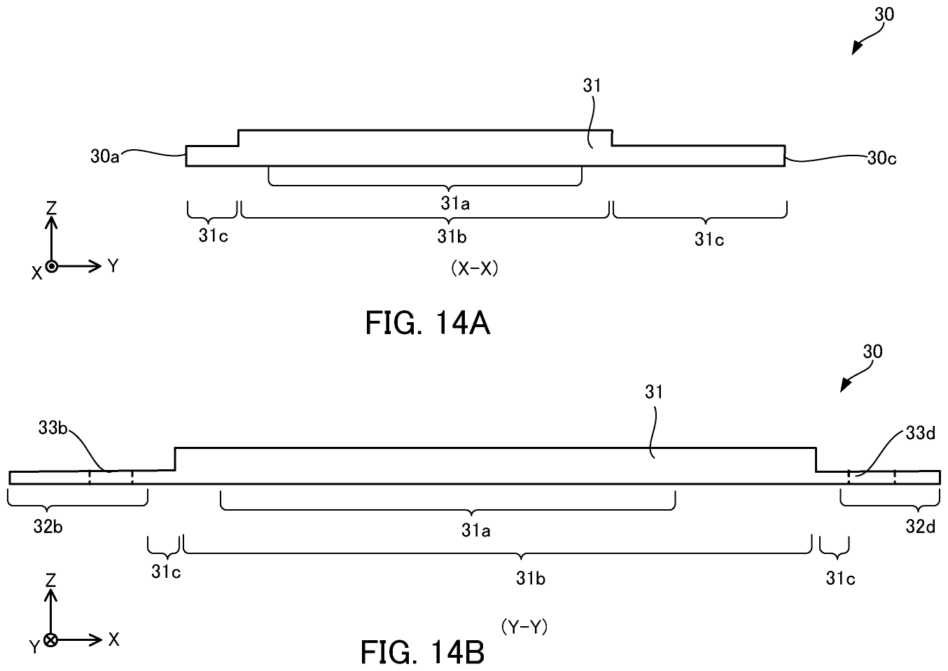

A second embodiment will now be described, in which a heat dissipation base 30 and a case 40 different from those of the first embodiment are provided. First, the heat dissipation base 30 of the second embodiment will be described with reference to FIGS. 13, 14A, and 14B. FIG. 13 is a plan view of a heat dissipation base included in a semiconductor device according to the second embodiment. FIGS. 14A and 14B are sectional views of the heat dissipation base included in the semiconductor device according to the second embodiment. In this connection, FIG. 14A is a sectional view of the heat dissipation base 30 taken along a dash-dotted line X-X of FIG. 13, whereas FIG. 14B is a sectional view of the heat dissipation base 30 taken along a dash-dotted line Y-Y of FIG. 13.

The heat dissipation base 30 of the second embodiment includes a heat dissipation portion 31 and fastening portions 32b and 32d. The heat dissipation portion 31 is rectangular in plan view and is surrounded on its four sides thereof by side surfaces 30a to 30d in order. The side surfaces 30a and 30c correspond to the long sides, whereas the side surfaces 30b and 30d correspond to the short sides. On the front surface of the heat dissipation portion 31, a heat dissipation area 31b including a unit area 31a and an outer peripheral area 31c outside the heat dissipation area 31b are set. The heat dissipation area 31b of the heat dissipation portion 31 is thicker than the outer peripheral area 31c thereof.

The fastening portions 32b and 32d are integrally provided on the side surfaces 30b and 30d of the heat dissipation portion 31, respectively. The fastening portions 32b and 32d each have a trapezoid shape (an isosceles trapezoid shape) in plan view, as in the first embodiment. The base sides of the fastening portions 32b and 32d are integrally provided on the side surfaces 30b and 30d of the heat dissipation portion 31, respectively. In this connection, as described earlier, in plan view, the base side of the fastening portion 32b means the +X-side side surface thereof, and the base side of the fastening portion 32d means the −X-side side surface thereof. Furthermore, in plan view, the top side of the fastening portion 32b means the −X-side side surface thereof, and the top side of the fastening portion 32d means the +X-side side surface thereof. In addition, fastening holes 33b and 33d are formed in the fastening portions 32b and 32d, respectively. These fastening portions 32b and 32d have the same thickness as the outer peripheral area 31c of the heat dissipation portion 31. That is, the heat dissipation base 30 varies in thickness in the heat dissipation area 31b and in the outer peripheral area 31c and fastening portions 32b and 32d. The front surface of the heat dissipation area 31b is located higher than the front surfaces of the outer peripheral area 31c and fastening portions 32b and 32d.

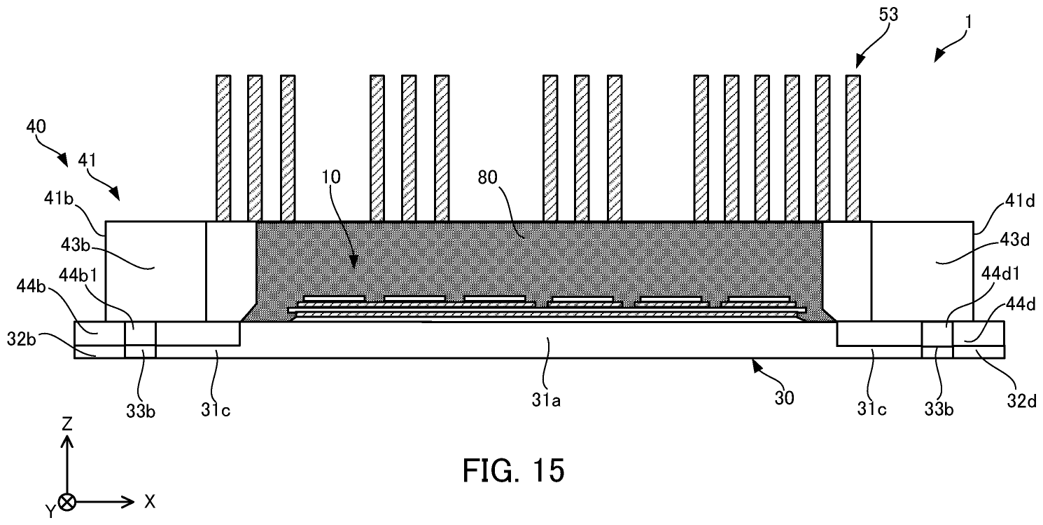

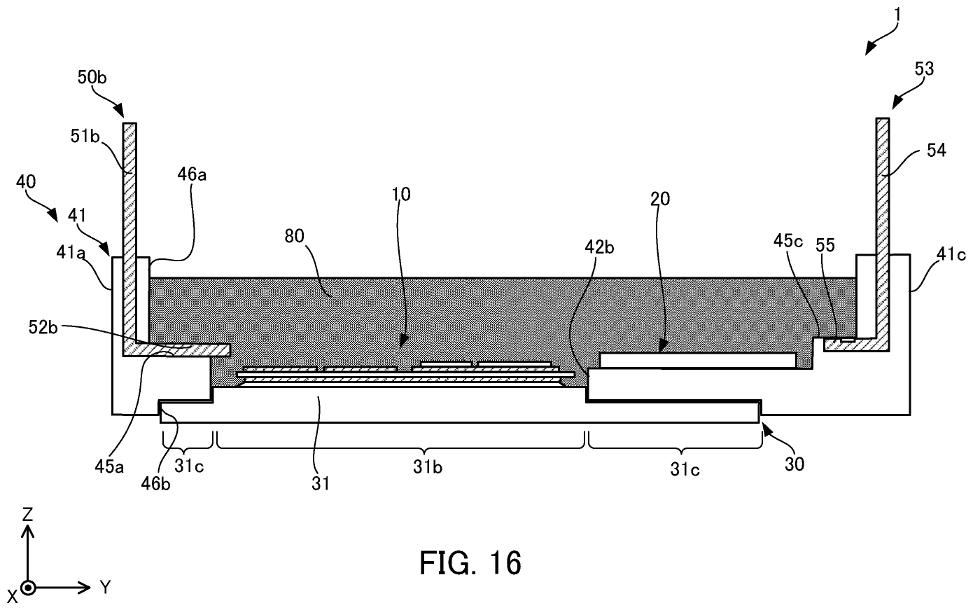

The following describes a case 40 of the second embodiment attached to the heat dissipation base 30 with reference to FIGS. 15 and 16. FIG. 15 is a sectional view of the semiconductor device along a long-side direction according to the second embodiment. FIG. 16 is a sectional view of the semiconductor device along a short-side direction according to the second embodiment. In this connection, FIGS. 15 and 16 correspond to the sectional views of FIGS. 3 and 2, respectively. In addition, the illustration of the control wires 61, electrical wires 62, main current wires 63, and control ICs 21 is omitted in FIGS. 15 and 16.

Protection portions 44b and 44d are formed on the rear surface of a frame portion 41 of the case 40 of the second embodiment so as to correspond not only to the fastening portions 32b and 32d but also to the outer peripheral area 31c. This case 40 is attached to the heat dissipation base 30, and wiring and sealing using the sealing member 80 are performed, thereby obtaining the semiconductor device 1. As illustrated in FIGS. 15 and 16, in this semiconductor device 1, the protection portions 44b and 44d of the case 40 are placed on the fastening portions 32b and 32d and outer peripheral area 31c of the heat dissipation base 30, and the fixing holes 44b1 and 44d1 of the case 40 are aligned with the fastening holes 33b and 33d of the heat dissipation base 30. In addition, an insulated circuit substrate 70 having first semiconductor chips 75 and second semiconductor chips 76 mounted thereon on the heat dissipation base 30 is accommodated in the case 40 from a bottom opening 46b of the case 40.

When this semiconductor device 1 is placed on a mounting object 2, and is fastened thereto by screwing screws into the fixing holes 44b1 and 44d1 and fastening holes 33b and 33d and then into the screw holes 2a of the mounting object 2, the fastening portions 32b and 32d and outer peripheral area 31c of the heat dissipation base 30 deform due to stress since the fastening portions 32b and 32d and outer peripheral area 31c are thinner than the heat dissipation portion 31. This reduces the occurrence of stress inside the semiconductor device 1 and accordingly reduces the occurrence of cracks in the insulated circuit substrate 70 and the bonding material bonding the insulated circuit substrate 70 to the heat dissipation base 30. In addition, since the case 40 is provided with the protection portions 44b and 44d, the frame portion 41 becomes thick around the areas where the fastening is done. This increases the strength of the case 40 and enhances resistance to external impacts and stress caused by the screwing, which results in preventing a reduction in the reliability of the semiconductor device 1. In addition, the heat dissipation base 30 of the second embodiment has a smaller volume than the heat dissipation base 30 of the first embodiment. Therefore, the cost of the heat dissipation base 30 is reduced, and the manufacturing of the semiconductor device 1 is streamlined.

The disclosed technique makes it possible to reduce the occurrence of damage inside a semiconductor device and to prevent a reduction in the reliability of the semiconductor device.

All examples and conditional language provided herein are intended for the pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although one or more embodiments of the present invention have been described in detail, it should be understood that various changes, substitutions, and alterations could be made hereto without departing from the spirit and scope of the invention.

What is claimed is:

1. A semiconductor device, comprising:
a semiconductor chip;
a substrate, with the semiconductor chip bonded to a front surface thereof;
a heat dissipation base of a plate shape, the heat dissipation base including:
a heat dissipation portion, and
a fastening portion connected to the heat dissipation portion without overlapping each other in a plan view of the semiconductor device,
the heat dissipation portion having a substrate area set on a front surface thereof, the substrate being disposed in the substrate area, the fastening portion having a fastening hole formed therein; and
a case of a frame shape, the case including an opening area at a center thereof and a protection portion beside the opening area, the protection portion having a fixing hole formed therein corresponding to the fastening hole, the case being disposed on the heat dissipation base so that the substrate is accommodated in the opening area and the protection portion is disposed on the fastening portion, wherein
a boundary between the fastening portion and the heat dissipation portion is located outside the opening area of the case in the plan view, and
the boundary or the fastening portion is located lower than the front surface of the heat dissipation portion in a side view of the semiconductor device.

2. The semiconductor device according to claim 1, wherein
the heat dissipation portion of the heat dissipation base is rectangular in the plan view, and
the fastening portion is provided in plurality, and the plurality of fastening portions are respectively provided on a pair of short sides of the heat dissipation portion opposite to each other.

3. The semiconductor device according to claim 2, wherein
in a width direction parallel to the pair of short sides of the heat dissipation portion, each of the fastening portions has a width equal to that of the short sides of the heat dissipation portion.

4. The semiconductor device according to claim 2, wherein the plurality of fastening portions includes four fastening portions respectively provided at four corners of the heat dissipation portion.

5. The semiconductor device according to claim 4, wherein the four fastening portions each have a fan shape.

6. The semiconductor device according to claim 2, wherein the plurality of fastening portions are respectively provided on the pair of short sides of the heat dissipation portion so as to project outward from the pair of short sides.

7. The semiconductor device according to claim 6, wherein the boundary crosses an area of the fastening portion projecting from the pair of short sides of the heat dissipation portion in the plan view.

8. The semiconductor device according to claim 1, wherein a groove is continuously formed only on the boundary in the plan view.

9. The semiconductor device according to claim 8, wherein the groove has a concave shape, a U-shape, or a V-shape in a cross-sectional view thereof.

10. The semiconductor device according to claim 1, wherein a rigidity of the fastening portion is less than a rigidity of the heat dissipation portion.

11. The semiconductor device according to claim 10, wherein a thickness of the fastening portion is less than a thickness of the heat dissipation portion.

12. The semiconductor device according to claim 11, wherein the thickness of the fastening portion is 30% or less of the thickness of the heat dissipation portion.

13. The semiconductor device according to claim 11, wherein a thickness of the protection portion is approximately equal to a distance from a front surface of the fastening portion to the front surface of the heat dissipation portion in a thickness direction of the semiconductor device.

14. The semiconductor device according to claim 13, wherein in the side view, an inner wall of the protection portion faces the opening area, and is in contact with a step formed by the fastening portion and the heat dissipation portion.

15. The semiconductor device according to claim 10, wherein the boundary is spaced at least a predetermined distance from the substrate area of the heat dissipation portion in the plan view.
